(19) United States
(12) Patent Application Publication
(10) Pub. No.: US 2002/0166697 A1
(43) Pub. Date: Nov. 14, 2002

(54) Circuit board construction

(75) Inventors: Mark L. Janecek, Endicott, NY (US); John S. Kresge, Binghamton, NY (US); Mark V. Pierson, Binghamton, NY (US); Thurston B. Youngs JR., Wappingers Falls, NY (US)

Correspondence Address: Mark Levy, Salzman & Levy, 19 Chenango St., Ste. 902, Binghamton, NY, 13901, US

(73) Assignee: International Business Machines Corporation, Armonk, NY

(21) Appl. No.: 09/853,506

(22) Filed: May 11, 2001

(51) Int. Cl. H05K 1/14; H05K 3/36

(52) U.S. Cl. 174/262; 174/255; 361/794; 29/830

(57) ABSTRACT

An improved circuit board construction featuring a multilayered, laminated structure having an intermediate power core layer having conductive adhesive-filled via through holes. The via through holes of the intermediate power core layer make electrical connection with metallic pads of conductive vias of adjacent outer signal core layers when the layers are laminated.

### FIELD OF THE INVENTION

The present invention relates to circuit boards and, more particularly, to a new multilayered circuit board structure that electrically connects the laminated circuit board layers by filling the via through holes of the inner power core layer with conductive adhesive, the conductive power core vias making contact with the metal pads of the conductive vias of the outer signal layers, upon lamination.

### BACKGROUND OF THE INVENTION

The processes for manufacturing circuit boards are varied, with each method trying to achieve a more cost effective way to achieve a highly complex circuit structure.

In U.S. Pat. No. 5,920,123, issued on Jul. 6, 1999, to Moden for MULTICHIP MODULE ASSEMBLY HAVING VIA CONTACTS AND METHOD OF THE SAME, a circuit board construction is illustrated wherein traces of electrically conductive materials are deposited in vias of a circuit layer by stencil printing or syringe dispensing techniques. Bonding pads disposed on an adjacent layer align with the vias, and make electrical contact with the conductive materials deposited therein. The via and pad connections, however, do not teach or suggest via/core connections, as illustrated in the current invention.

In U.S. Pat. No. 5,157,477, issued to Chance on Oct. 20, 1992 for MATCHED IMPEDANCE VERTICAL CONDUCTORS IN MULTILEVEL DIELECTRIC LAMINATED WIRING, assigned to a common assignee, a multiplane, laminated circuit board is shown wherein a plurality of conductive via holes are aligned with a flush or countersunk pad. The construction features electrical impedance matching within a core, but fails to address core to core connectivity, as taught by the present invention.

In U.S. Pat. No. 5,574,630, issued to Kresge et al on Nov. 12, 1996 for LAMINATED ELECTRONIC PACKAGE INCLUDING A POWER/GROUND ASSEMBLY, assigned to a common assignee, a printed circuit board sub-assembly is depicted, featuring in one embodiment thereof, a flexible substrate with via holes. The features two multilayered, multi-density cores that are connected by a copper-to-copper pad electrical interface.

In U.S. Pat. No. 5,442,144, issued to Chen et al on Aug. 15, 1995 for MULTILAYERED CIRCUIT BOARD, assigned to a common assignee, a method of making a multilayered circuit board is illustrated. The method features solder plating via pads to each other by reflow temperature techniques during the lamination process. By contrast, the present invention presents a method of bonding, that uses electrically conductive adhesives at this interface.

In U.S. Pat. No. 5,298,685, issued on Mar. 29, 1994 to Bindra et al for INTERCONNECTION METHOD AND STRUCTURE FOR ORGANIC CIRCUIT BOARDS, assigned to a common assignee, polymeric subcomposites of a circuit board are interconnected by dendrites on specific areas of the copper pads.

In U.S. Pat. No. 5,229,550, issued to Bindra et al on Jul. 20, 1993 for ENCAPSULATED CIRCUITIZED POWER CORE ALIGNMENT AND LAMINATION, assigned to a common assignee, a structure and method is shown for making high density circuit boards. The cores of the circuit board are connected with or solder.

The present invention comprises a multi-layered, laminated circuit board construction, wherein conductivity is transferred from signal core to signal core through a power core. The via through holes of the power core structure are filled with conductive adhesives, and then “B” stage cured. Upon lamination of all of the core layers, an electrical connection is achieved between the conductive via through holes of the outer signal layers when their metallic pads contact the conductive adhesive disposed in the vias of the inner power core layer.

In another embodiment of the current invention, the power core pads are covered with conductive adhesive. Electrical contact with the adjacent metallic pads of the conductive vias of the signal cores is achieved upon lamination of the inner and outer core layers.

### SUMMARY OF THE INVENTION

In accordance with the present invention, there is provided an improved circuit board construction featuring a multilayered, laminated structure. Conductive adhesives used to provide electrical connectivity between outer signal core layers through an inner power core layer. The via through holes of the intermediate power core layer are filled with conductive adhesive, and then “B” stage cured. Upon the lamination of all the cores, a connection is achieved between the metallic pads of the conductive vias of the outer signal core layers with the conductive adhesive disposed in the vias of the inner power core layer.

In another embodiment of the current invention, the vias of the inner power core layer are covered at their surface with conductive adhesive pads. These conductive pads make electrical contact with the adjacent metallic pads of the via through holes carried by the outer signal core layers when the inner and outer layers are laminated.

It is an object of the present invention to provide an improved circuit board construction using conductive adhesives.

It is another object of this invention to provide a multilayered, laminated circuit board, wherein electrical connectivity between the outer signal core layers and the inner power core layer is achieved by using conductive adhesive to fill the vias of the power core layer.

### DESCRIPTION OF THE DRAWINGS

A complete understanding of the present invention may be obtained by reference to the accompanying drawings, when considered in conjunction with the subsequent detailed description, in which:

FIG. 1 illustrates an exploded, sectional, schematic view of a first embodiment of the multilayered circuit board structure of this invention;

FIG. 2 depicts an exploded, sectional, schematic view of a second embodiment of the multilayered circuit board structure of this invention; and

FIG. 3 shows an exploded, sectional, schematic view of a third embodiment of the multilayered circuit board structure of this invention.

For purposes of brevity and clarity, like elements and components will bear the same numbering and designations throughout the figures.

### DESCRIPTION OF THE PREFERRED EMBODIMENT

Generally speaking, a multilayered construction of a circuit board is illustrated. Conductive adhesives are used to provide electrical connectivity between outer signal core layers and an inner power core layer in the preferred embodiment. The via through holes of the intermediate power core layer are filled with conductive adhesives, and then “B” stage cured. Upon lamination of all of the core layers, an electrical connection is achieved throughout the layers when the metallic pads of the outer signal layers make contact with the conductive adhesive-filled vias of the inner power core layer.

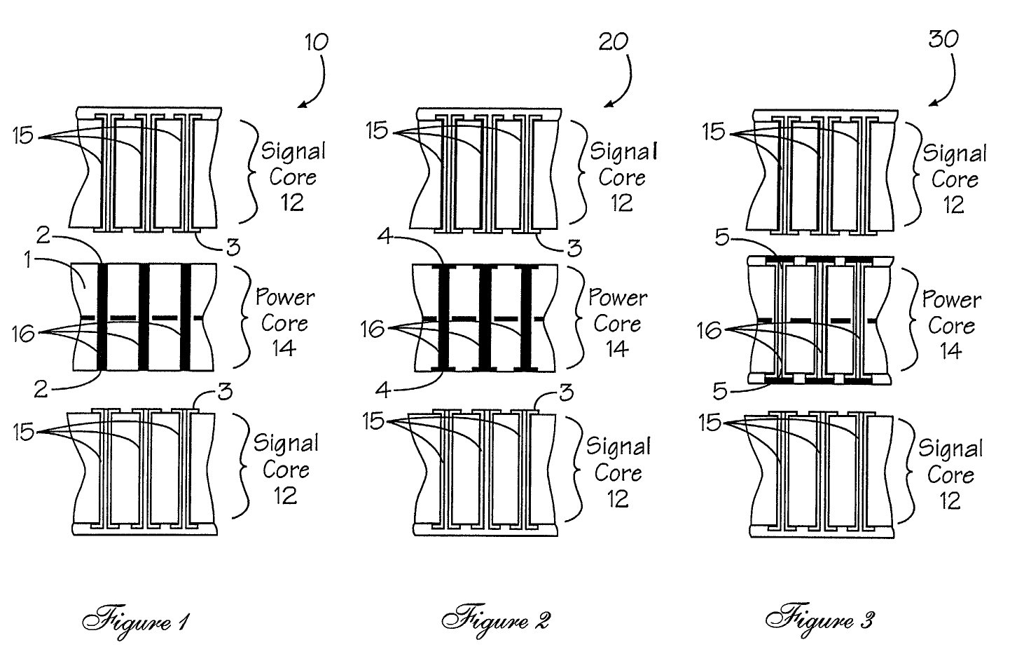

Now referring to FIG. 1, a multilayered circuit board 10 of this invention is shown in exploded, sectional view. The circuit board 10 comprises two, outer, signal core layers 12, and a middle power core layer 14. It should be understood, however, that any number of layers 12, 14 can be used to create a multilayer board 10, and the invention is not meant to be limited to the layers shown herein for descriptive purposes only. The power core layer 14 comprises a plurality of via through holes 16 that are filled with a conductive adhesive 1, such as: ABLESTICK 8175. The adhesive is “B” stage cured.

The circuit board 10 is fabricated by laminating the outer signal core layers 12 with the intermediate power core layer 14. An electrical connection is achieved when the layers 12 and 14 are laminated together. The connection results from the contact of the precious metal coated pads 3 of the conductive vias 15 of the signal core layers 12 with the conductive surfaces 2 of the conductive adhesive-filled vias 16 of the power core layer 14.

Referring to FIG. 2, a circuit board 20, depicted in exploded, sectional view, illustrates a second embodiment of the invention. In this embodiment, conductive adhesive-filled via through hole surfaces 4 of power core layer 14 are slightly undercut. The undercut provides a larger contact area between the precious metal coated pads 3 of the conductive via through holes 15 of the signal core layers 12 and the conductive surfaces 4 of the via through holes 16 of the power core layer 14. The layers 12 and 14 are laminated under high heat and pressure.

Referring to FIG. 3, an exploded, sectional view of a circuit board 30 depicts a third embodiment of this invention. In this embodiment, conductive adhesive is applied to precious metal coated pads 5 of the via through holes 16 of the power core layer 14, prior to lamination. Electrical connectivity is achieved between the conductive via through holes 15 of the outer signal core layers 12 and the conductive via through holes 16 of the inner power core layer 14 after lamination.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A multi-layered circuit structure, comprising:
a first substrate having conductive via through holes disposed therein; and
a second substrate laminated to said first substrate and having conductive, adhesive-filled via through holes that align with, and make electrical contact with, the conductive via through holes of said first substrate upon lamination of said first and second substrates.

2. The multi-layered circuit structure in accordance with claim 1, wherein said first substrate comprises a signal core layer, and said second substrate comprises a power core layer.

3. The multi-layered circuit structure in accordance with claim 1, wherein said first substrate comprises a pair of outer signal core layers, and said second substrate comprises an inner power core layer sandwiched between said pair of outer signal core layers.

4. The multi-layered circuit structure in accordance with claim 3, wherein said via through holes of said inner power core layer comprise undercut contact surfaces, and said via through holes of said signal layer have metallic pads that make electrical contact with said undercut contact surfaces of said via through holes of said inner power core layer.

5. A multi-layered circuit structure, comprising:
a first substrate having conductive via through holes disposed therein; and
a second substrate laminated to said first substrate, and having via through holes comprising conductive adhesive coated pads that align with, and make electrical contact with, the conductive via through holes of said first substrate upon lamination of said first and second substrates.

6. The multi-layered circuit structure in accordance with claim 5, wherein said first substrate comprises a signal core layer, and said second substrate comprises a power core layer.

7. The multi-layered circuit structure in accordance with claim 5, wherein said first substrate comprises a pair of outer signal core layers, and said second substrate comprises an inner power core layer sandwiched between said pair of outer signal core layers.

8. A method of fabricating a multi-layered circuit, comprising the steps of:
filling via through holes of a first substrate with conductive adhesive;
aligning said via through holes of said first substrate with conductive via through holes of a second substrate; and
laminating together said first and second substrates.

9. The method in accordance with claim 8, wherein said first substrate comprises a signal core layer, and said second substrate comprises a power core layer.

10. The method in accordance with claim 8, wherein said first substrate comprises a pair of outer signal core layers, and said second substrate comprises an inner power core layer sandwiched between said pair of outer signal core layers.
